(19) United States
(12) Patent Application Publication
(10) Pub. No.: US 2004/0046225 A1
(43) Pub. Date: Mar. 11, 2004

(54) Semiconductor power component

(76) Inventor: Wolfgang Feiler, Reutlingen (DE)

Correspondence Address: Striker Striker & Stenby, 103 East Neck Road, Huntington, NY, 11743, US

(21) Appl. No.: 10/276,568

(22) PCT Filed: May 10, 2001
(86) PCT No.: PCT/DE01/01774

(30) Foreign Application Priority Data
May 16, 2000 (DE) 100 23 956.0

(51) Int. Cl. H01L 23/58

(52) U.S. Cl. 257/492

(57) ABSTRACT

For signal transmission between the high-pressure side (2) and the low-pressure side (3) of a semiconductor power component (1), with a reduced surface field (RESURF) region (4) disposed between the high-pressure side (2) and the low-pressure side (3), it is proposed that at least one polysilicon resistor (5) be provided, which is disposed above the RESURF region (4) and is electrically insulated from it, as a result of which a high off-state voltage resistance is assured.

### PRIOR ART

The invention relates to a semiconductor power component, with a reduced surface field (RESURF) region disposed between the high-pressure side and the low-pressure side.

The semiconductor power component can for instance be a diode, an LIGBT, an LDMOS, or a bipolar transistor.

Laterally mounted power components often include a RESURF region with a refined dopant dosage, which results in a tub-shaped course of the field intensity at the semiconductor surface of the RESURF region and a course of the potential that is linear over wide portions. This effect is utilized to achieve a high blocking-state capability on a minimal chip surface area. Characteristically, such power components have a fingerlike interdigital structure, so that the high-pressure side and the low-pressure side mesh with one another like fingers and are separated from one another by the RESURF region that picks up the blocking-state voltage.

In the literature, J. A. Appels et al, IEDM Tech. Dig., 1979, pages 238-241, describe the RESURF principle for achieving a high blocking-state voltage strength with the least possible space required for flat p-n junctions.

In the literature, K. Endo et al, ISPSD '94 Conference Proceedings, pages 379-383, describe a spiral polysilicon resistor which is disposed as high-voltage passivation above the RESURF region of an SOI lateral diode, an SOI LDMOS, and an SOI LIGBT. In the case of the LDMOS and the LIGBT, the polysilicon resistor is connected on one side to the anode and on the other to the gate. In the case of the diode, one side of the polysilicon resistor is connected to the anode, and the other side is connected to the cathode. In all three cases described, the polysilicon resistor is used to increase the high-voltage strength of flat p-n junctions.

When power components of the type in question here are used, the necessity often arises of achieving a signal transmission from the high-pressure side to the low-pressure side. One example of a use of such a signal transmission is limiting overvoltages and on-state currents to allowable maximum values, which on the one hand serves to protect the power component itself and on the other also to protect its peripheral wiring. Limiting overvoltages and on-state currents to allowable maximum values is achieved in practice often with the aid of sense circuits and trigger and evaluation circuits, which can advantageously be integrated onto the power component chip. Current detection by the sense circuit, for instance, could be done with the aid of one segment of the surface of the power component, including the protective resistor. The current signal detected is prepared with the aid of the trigger and evaluation circuit and optionally carried onward. The trigger and evaluation circuit can optionally, by means of a suitable triggering of the component input, limit the current to allowable values.

In lateral power components, the problem often arises that the sense circuit is at the potential of the high-pressure side, while the trigger and evaluation circuit is at the potential of the low-pressure side, which means that a signal transfer must be made between the high-pressure side and the low-pressure side of the power component. This signal transfer should be as neutral as possible in terms of surface area and should not reduce the blocking-state voltage strength of the power component.

### ADVANTAGES OF THE INVENTION

To achieve a signal transmission from the high-pressure side to the low-pressure side of a semiconductor power component of the kind in question here, according to the invention, at least one polysilicon resistor is provided, which connects the high-pressure side to the low-pressure side. This polysilicon resistor is disposed above the RESURF region and is electrically insulated from it.

According to the invention, it has been recognized that for a signal transmission from the high-pressure side to the low-pressure side of a power component, an element should be used that has a linear voltage drop along its length, so as not to interfere with the optimal field or potential distribution in the RESURF region. The use of a linear resistor is therefore proposed. Also according to the invention, it has been recognized that in the event of power component failure, high current densities and carrier densities (high injection) exist, so that the resistor must be insulated against the effects of this current flow. Finally, according to the invention, it has been recognized that these requirements are met quite well by a polysilicon resistor that crosses the RESURF region and is electrically insulated from it.

Accordingly, by way of the polysilicon resistor proposed according to the invention, the transmission of measurement signals and, in cooperation with the RESURF region disposed below it, the achievement of a high blocking-state voltage strength while requiring minimal space are simultaneously possible. In contrast to that, signal transmission via a diffused resistor would be impossible, in the event of failure of a bipolar power component, since the signal transmission would be interfered with because of the high injection typically present. As already noted, such an effect is precluded in the case of the polysilicon resistor proposed according to the invention, since it is completely insulated from the semiconductor.

In order to keep the leakage current low at a high blocking-state voltage of several hundred volts, the polysilicon resistor must be large, that is, larger than several kOhm. Accordingly, it should be as long as possible. This length can advantageously be achieved in a space-saving way by having the polysilicon resistor not cross the RESURF region over the shortest distance but rather in a meandering pattern. To that end, the polysilicon resistor could be laid in the form of a spiral meander or in the form of a zigzag meander from the high-pressure side to the low-pressure side.

It proves to be especially advantageous, because it is easy to attain, to insulate the polysilicon resistor from the RESURF region or semiconductor by means of a field oxide. However, the use of other electrically insulating materials would also be conceivable.

There are now various ways of advantageously embodying and refining the teaching of the present invention. To that end, reference is made on the one hand to the claims dependent on claim 1 and on the other to the explanation below of a plurality of exemplary embodiments of the invention in conjunction with the drawings.

### DRAWINGS

FIG. 1 shows the plan view on a power component of the invention with a RESURF region and with four polysilicon resistors.

FIG. 2 shows the plan view on a further power component of the invention, with two polysilicon resistors in the form of zigzag meanders.

FIG. 3 shows a cross section, taken along the intersection axis AA′ shown in FIG. 1 for a lateral pnp transistor.

FIG. 4 shows a cross section, taken along the intersection axis AA′ shown in FIG. 1 for a lateral pnp diode.

FIG. 5 shows a cross section, taken along the intersection axis AA′ shown in FIG. 1 for an LDMOS.

FIG. 6 shows a cross section, taken along the intersection axis AA′ shown in FIG. 1 for an LIGBT.

FIG. 7 shows a cross section, corresponding to FIG. 6, through a lateral-vertical IGBT (LVIGBT), with the interconnection of the sense circuit and the trigger and evaluation circuit also shown.

FIG. 8 shows the situation shown in FIG. 7, in the form of a wiring sketch.

FIG. 9 shows the wiring sketch of a further LVIGBT with a sense circuit and a trigger and evaluation circuit.

FIG. 10 shows the plan view of an exemplary embodiment for connecting polysilicon resistors to the sense circuit and to the trigger and evaluation circuit, for the LVIGBT shown in FIG. 9.

FIG. 11 shows the plan view of a further exemplary embodiment for connecting polysilicon resistors to the sense circuit and to the trigger and evaluation circuit, for the LVIGBT shown in FIG. 9.

FIG. 12 shows an enlarged plan view on the region shown in FIG. 10 of the resistor 16.

FIG. 13 shows a cross section through the region shown in FIG. 12, taken along the section BB′.

FIG. 14 shows a plan view on the cathode side of an LVIGBT without metallizing or an intermediate dielectric.

FIG. 15 shows a plan view on the cathode side of an LVIGBT with metal.

FIG. 16 shows a cross section taken along the intersection axis CC′ shown in FIG. 15.

FIG. 17 shows a cross section taken along the intersection axis DD′ shown in FIG. 15.

FIG. 18 shows a plan view on the cathode side of an LVIGBT with metallizing and with an intermediate dielectric.

FIG. 19 shows a cross section taken along the intersection axis EE′ shown in FIG. 18.

FIG. 20 shows a cross section taken along the intersection axis FF′ shown in FIG. 18.

### DESCRIPTION OF THE EXEMPLARY EMBODIMENTS

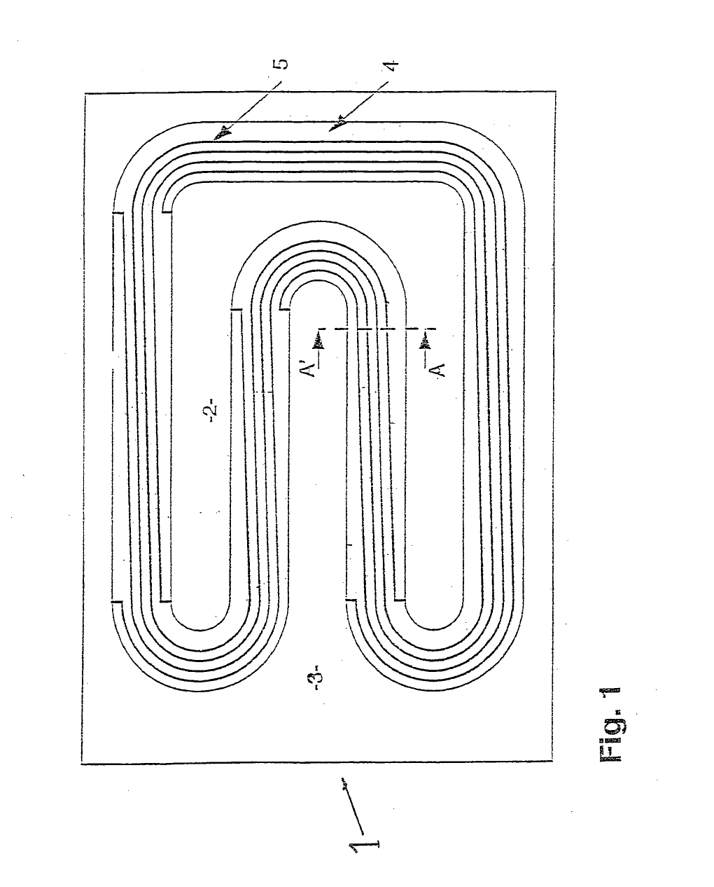

As already noted, FIG. 1 shows the plan view on a semiconductor power component 1 of the invention, with a RESURF region 4 disposed between the high-pressure side 2 and the low-pressure side 3. The high-pressure side 2 and the low-pressure side 3 of the power component 1 shown here mesh with one another like fingers and are separated from one another by the RESURF region 4. It should also be noted at this point that the power component 1 shown can for instance be a diode, an LIGBT, an LDMOS, or a bipolar transistor.

According to the invention, a polysilicon resistor 5 is disposed above the RESURF region 4—and in this case in fact four polysilicon resistors 5 are so disposed. In the exemplary embodiment shown here, the polysilicon resistors 5 are laid in a meandering pattern within the finger structure of the RESURF region 4, from the high-pressure side 2 to the low-pressure side 3. The polysilicon resistors 5 are electrically insulated from the RESURF region 4, which is clearly shown by FIGS. 3-6.

In the exemplary embodiment shown here, the four polysilicon resistors 5 begin at equal intervals from one another from the high-pressure side 2 and end in the low-pressure side 3. It is advantageous if the polysilicon resistors 5 have the minimum possible width and the minimum possible spacing from one another, or from winding to winding, attainable by the applicable production process and if they extend all the way around the high-pressure side 2 as many times as the aforementioned design rules allow.

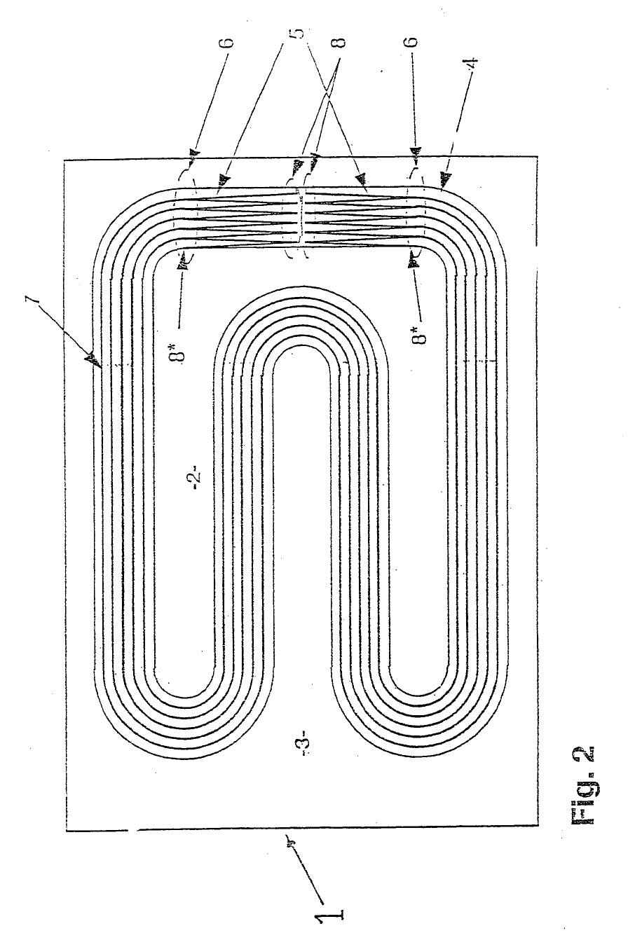

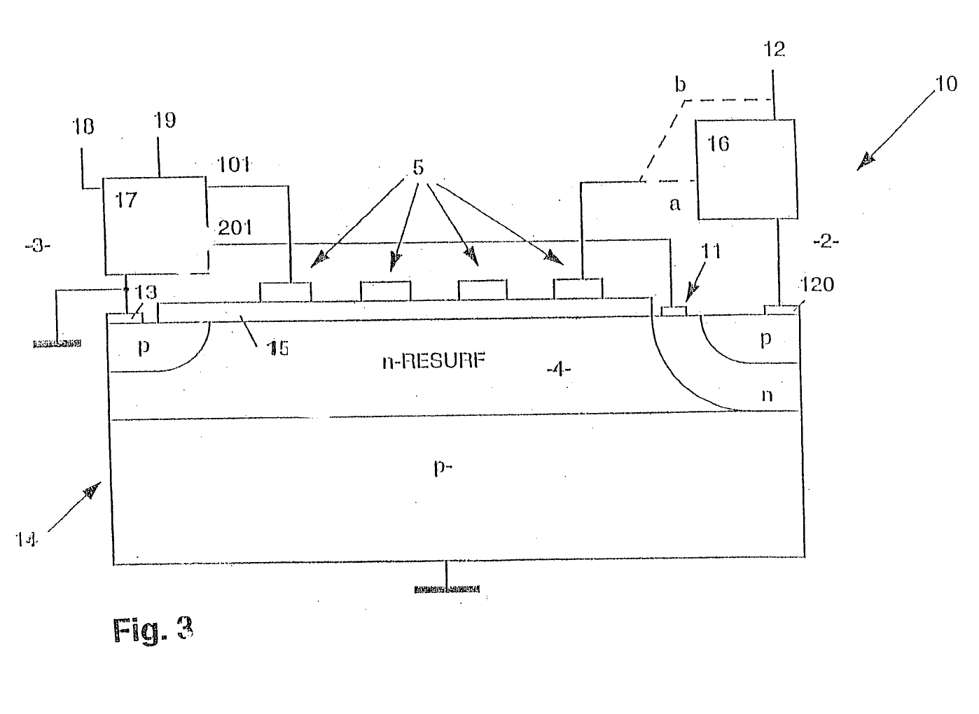

Another possibility for disposing polysilicon resistors 5 on the RESURF region 4 of a power component 1 is shown in FIG. 2. Here, two polysilicon resistors 5, each in the form of a zigzag meander, are provided, whose ends are located on the low-pressure side 3 and whose beginnings 8* are located on the high-pressure side 2. Via these polysilicon resistors 5 extending in a zigzag meandering pattern, a signal transfer between the high-pressure side 2 and the low-pressure side 3 is possible. To attain a high blocking-state capability, the outer corners 6 of the zigzag meanders are each connected to polysilicon strips 7. These polysilicon strips 7 extend on tracks with an approximately constant spacing from the high-pressure side 2 or low-pressure side 3, respectively, in a meandering pattern along the RESURF region 4. By means of this embodiment, peaks in the electrical field intensity or vertical field exaggerations in the semiconductor under the outer corners 6 of the zigzag meandering polysilicon resistors 5 are averted. This is a precaution against an avalanche breakdown of the component at even low voltages and thus a reduction in blocking-state capability. Moreover, with the aid of the polysilicon strips 7, the potential course above the RESURF region 4 is stabilized, which also increases the stability of the component under high blocking-state voltage.

Vertical field exaggerations in the semiconductor under the inner ends 8 of the zigzag meandering polysilicon resistors 5 are minimized in the present exemplary embodiment by providing that these inner ends 8 are located as close as possible to one another.

In the event that only a single polysilicon resistor is needed, then in principle two possible designs can be considered. In the first variant, the polysilicon resistor is embodied as a single zigzag meander, which has two outer ends. These ends can be terminated by polysilicon strips as described. In the second variant, the polysilicon resistor comprises a parallel circuit of the plurality of zigzag meanders described above. The parallel circuit is obtained by connecting pairs of the originally adjacent inner ends of the plurality of zigzag meanders.

The embodiments, proposed in conjunction with FIG. 2, of the polysilicon resistors of the invention have the advantage over the forms proposed in conjunction with FIG. 1 of being simple, i.e., time-saving, to move around in the layout phase. By comparison, with the embodiments described in conjunction with FIG. 1, higher-impedance resistors can be achieved.

The lateral pnp transistor 10 shown in cross section in FIG. 3 has the terminal named base 11, emitter 120, and collector 13. Such a transistor can have an arbitrary number of fingers and can be produced on a p⁻ substrate, p⁻/p⁺ substrate, or SOI substrate. Shown in detail here is a variant on a p⁻ substrate 14. In each of these cases, the RESURF region 4 is then n-doped. The polysilicon resistor 5 disposed above the RESURF region 4 is electrically insulated from the RESURF region 4 by a field oxide layer 15.

In the exemplary embodiment shown here, the polysilicon resistor 5 is used for signal transmission between a sense circuit 16, which is at the potential of the high-pressure side 2, and a trigger and evaluation circuit 17, which is at the potential of the low-pressure side 3. The polysilicon resistor 5 is acted upon on the high-pressure side 2, namely on the emitter side, with a voltage signal on the order of magnitude of the emitter voltage, and for that purpose it can be connected alternatively directly to the external emitter terminal 12 of the sense circuit 16, as indicated by the line course b, or to the sense circuit 16, which is indicated by the line course a. The low-pressure side, that is, the side toward the collector, of the polysilicon resistor 5 is connected to the trigger and evaluation circuit 17 via a signal detection input 101.

The trigger and evaluation circuit 17 also has an optional status output 18 and a triggering input 19. The bipolar transistor 10 shown here can be triggered by an external signal source via the trigger input 19. The base terminal 11 can be triggered directly by the trigger and evaluation circuit 17. To that end, the trigger and evaluation circuit 17 has a trigger output 201 with a switch element with high-voltage strength. This can for instance be an npn or NMOS transistor, whose emitter or source, as applicable, is connected to ground potential and whose collector or drain, respectively, is connected to the base terminal 11.

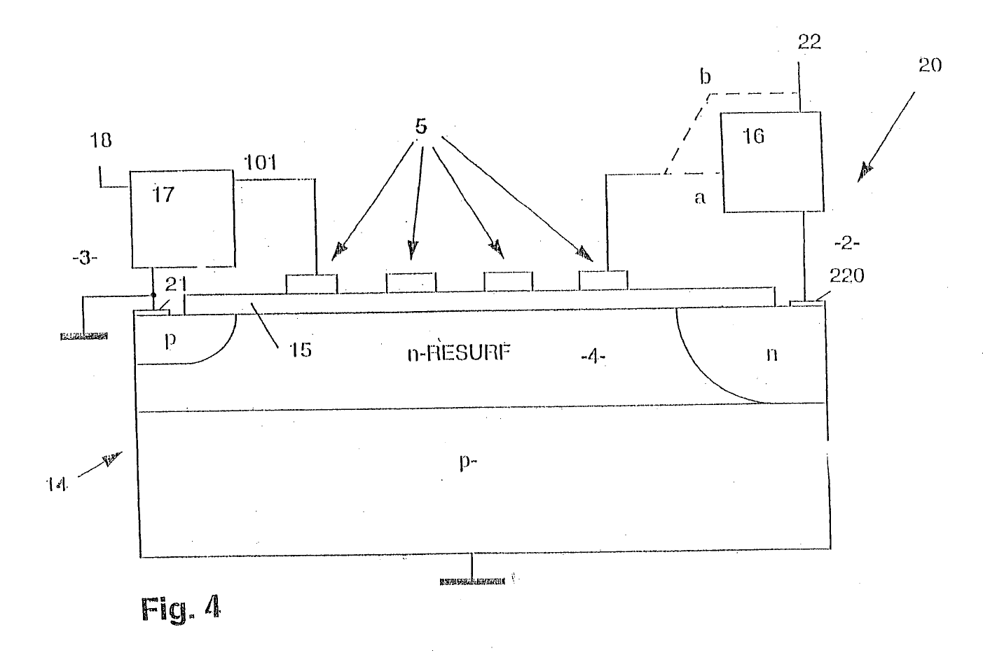

FIG. 4 shows a cross section, analogous to FIG. 3, through a lateral diode 20, which has terminals named anode 21 and cathode 220. The diode 20 can have an arbitrary number of fingers, and just like the pnp transistor shown in FIG. 3, it can be produced on a p⁻ substrate, a p⁻/p⁺ substrate, or an SOI substrate. What is shown in detail here is the variant on a p⁻ substrate 14. In these three cases, the RESURF region 4 always has n-doping. The polysilicon resistor 5 is again electrically insulated from the semiconductor substrate 14 by a field oxide layer 15. Moreover, here as well, the polysilicon resistor 5 serves the purpose of signal transmission between a sense circuit 16, which is at the potential of the high-pressure side 2, and a trigger and evaluation circuit 17, which is at the potential of the low-pressure side 3. The sense circuit 16 has an external cathode terminal 22 for connecting a load. Alternatively, on the high-pressure side 2 the polysilicon resistor 5 can be connected directly to this external cathode terminal 22, as indicated by the line course b, or to the sense circuit 16, as indicated by the line course a. The trigger and evaluation circuit 17 has a status input 18 and a signal detection input 101, by way of which latter input the polysilicon resistor 5 is connected to the trigger and evaluation circuit 17.

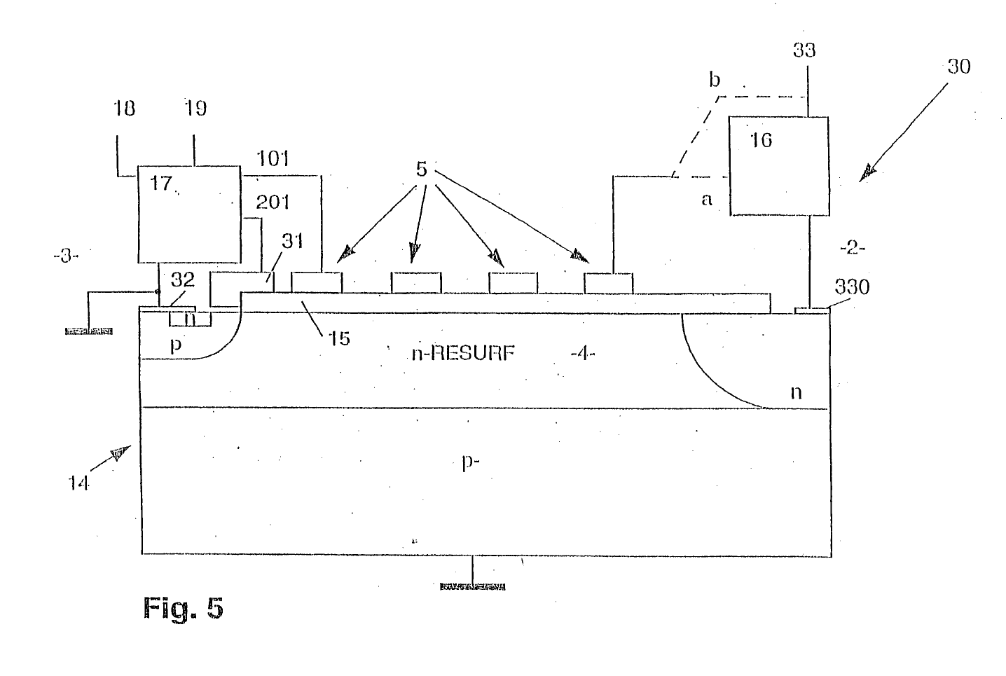

FIG. 5 shows a cross-sectional view, analogous to the FIGS. 3 and 4, of an LDMOS 30 having the terminal gate 31, source 32 and drain 330. An LDMOS of this kind can likewise have an arbitrary number of fingers and, like the components described above, can be produced on a p⁻, p⁻/p⁺, or SOI substrate. The variant on a p⁻ substrate 14 is shown in detail here. The polysilicon resistor 5, which here as well serves the purpose of signal transmission between a sense circuit 16, at the potential of the high-pressure side 2, and a trigger and evaluation circuit 17, at the potential of the low-pressure side 3, is electrically insulated from the semiconductor substrate 14 by a field oxide layer 15. Alternatively, on the high-voltage side, it can be connected directly to the external drain terminal 33 (line course b), or to the sense circuit 16 (line course a). On the low-voltage side, the polysilicon resistor 5 is connected to a signal detection input 101 of the trigger and evaluation circuit 17. The trigger and evaluation circuit 17 moreover has an optional status output 18 and a trigger input 19, by way of which latter input 19 the LDMOS 13 is triggerable from an external signal source. To that end, the trigger and evaluation circuit 17 has a trigger input 201, which is connected to the gate 31.

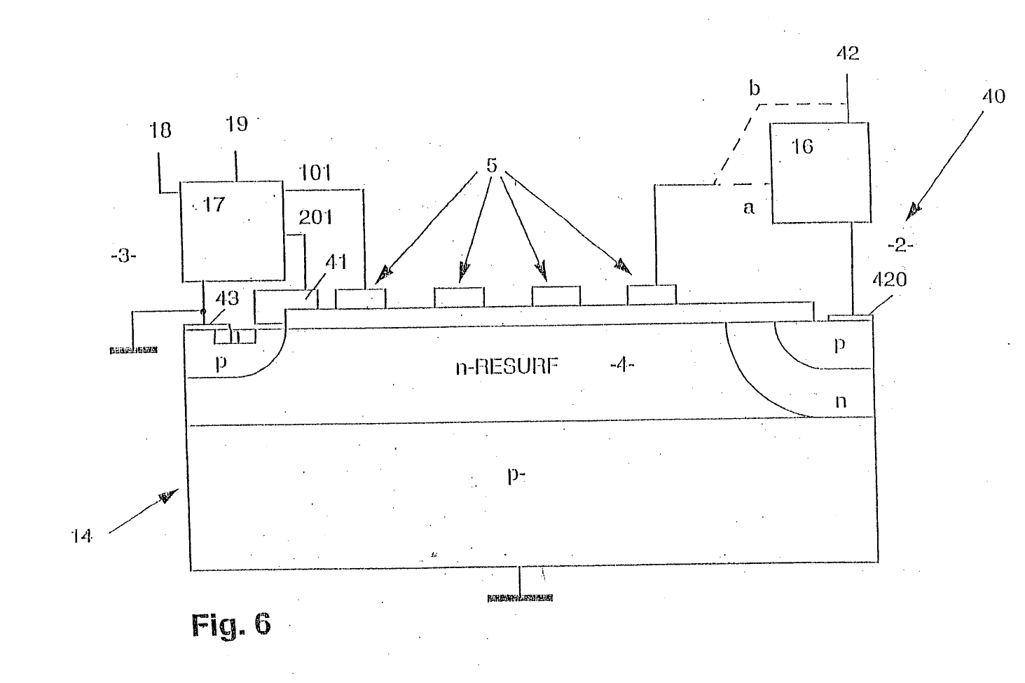

FIG. 6 shows a cross-sectional view, analogous to the FIGS. 3-5, of an LIGBT 40 having the terminal gate 41, anode 420 and cathode 43. An LIGBT of this kind can likewise have an arbitrary number of fingers and, like the components described above, can be produced on a p⁻, p⁻/p⁺, or SOI substrate, and the RESURF region 4 always has n-doping. The variant on a p⁻ substrate 14 is shown in detail here. Once again, the polysilicon resistor 5 is electrically insulated from the semiconductor substrate 14 by a field oxide layer 15. Here as well, it serves the purpose of signal transmission between a sense circuit 16, disposed on the high-voltage side, and a trigger and evaluation circuit 17, disposed on the low-voltage side. In the present exemplary embodiment, the polysilicon resistor 5 can alternatively be connected directly to the external anode terminal 42 (line course b), or to the sense circuit 16 (line course a). On the low-voltage side, the polysilicon resistor 5 is connected to a signal detection input 101 of the trigger and evaluation circuit 17. The trigger and evaluation circuit 17 moreover has an optional status output 18 and a trigger output 19, by way of which latter output the LIGBT 40 is triggerable from an external signal source. To that end, the trigger and evaluation circuit 17 includes a trigger output 201, which is connected to the gate 41, so that the trigger and evaluation circuit 17 can selectively act in regulating fashion on the gate 41.

It is understood that all the dopings mentioned in conjunction with FIGS. 3-6 may be transposed—that is, p instead of n—and the terminals and potentials shown should then be altered accordingly.

The sense circuit 16 and the trigger and evaluation circuit 17 could for instance be used to detect and limit the anode voltage of the LIGBT. For the explanation below, the signal course b has been selected, so that the sense circuit 16 can be replaced with a conductive connection. It is assumed that an inductive load is connected to the external anode terminal 42, and a current flows through this load; the LIGBT is assumed to be on. If the LIGBT is then turned off in response to a control signal at the trigger input 19, to which end the trigger output 201 of the trigger and evaluation circuit 17 reduces its voltage to values below the threshold voltage of the LIGBT, then the voltage at the anode terminal 420 or 42 then rises. This increase, unless further provisions are made, would generate such high anode voltages that the semiconductor component would reach its breakdown voltage.

To prevent an uncontrolled increase in the anode voltage, the voltage rise at the anode terminal 420 or 42 is transmitted as a current or voltage signal to the low-pressure side 3 via the meandering polysilicon resistor 5 and delivered to the signal detection input 101 of the trigger and evaluation circuit 17. The trigger and evaluation circuit 17 compares this signal with a reference value, and when this value is reached, the gate 41 is triggered via the trigger output 201 in such a way that the anode voltage is limited to a predetermined value.

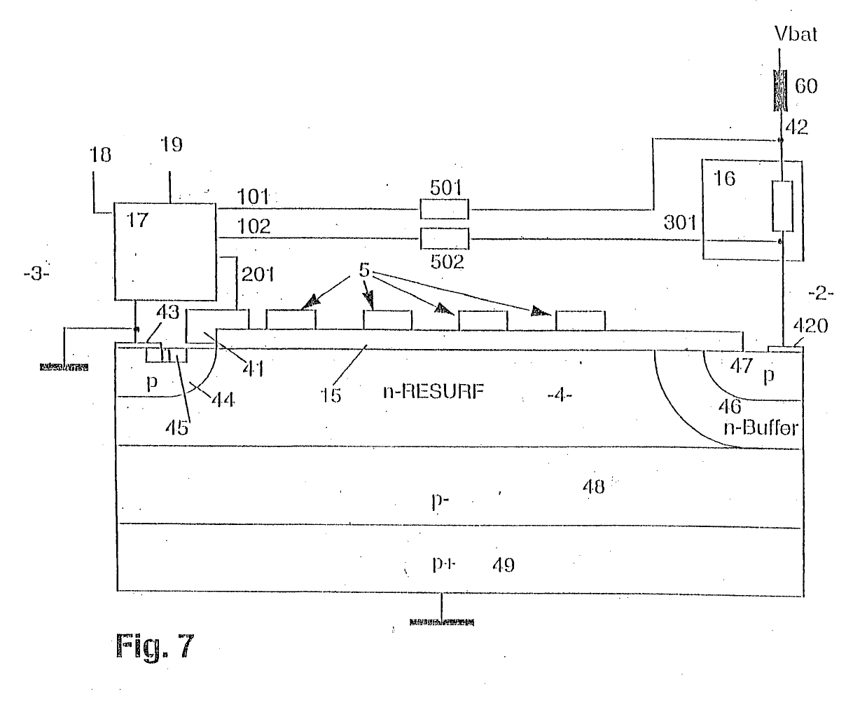

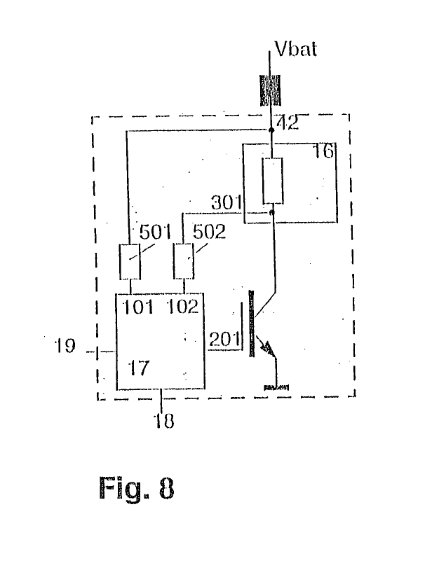

In conjunction with FIGS. 7 and 8, a lateral-vertical IGBT (LVIGBT) with current limitation and a current status output will be described below, in order to a provide a further exemplary embodiment for a sense circuit and a trigger and evaluation circuit.

The LVIGBT shown in FIG. 7 is produced on a p⁻/p⁺ substrate, but otherwise has the same design as the LIGBT shown in FIG. 6, so that the same reference numerals in both FIGS. 6 and 7 mean the same elements and circuit components. The external anode terminal 42 of the LVIGBT is connected here to an inductive load 60, which is supplied via an operating voltage source Vbat. In the exemplary embodiment shown here, a resistor 16 serves as the sense circuit 16 and can be embodied in the form of a polysilicon resistor, for instance. If a trigger voltage is supplied to the trigger and evaluation circuit 17 via the trigger input 19, then the trigger output 201 and thus the gate 41 assume a positive voltage; the LVIGBT is switched on: At the surface of the semiconductor below the gate 41, particularly in the p region 44, an inversion channel is created, whereupon electrons from the n region 45 are injected into the RESURF region 4. The p-anode 47 responds with a hole injection. As a consequence, the RESURF region 4 and large parts of the p⁻ region 48 are flooded with charge carriers and assume the status of the high injection. A current now flows from Vbat through the load 60 and the resistor 16, via the anode metallizing 420, the p-anode 47, and the n buffer 46. Some of the current flows away to ground, on the back side of the component, via the p⁻ region 48 and the p⁺ region 49, and the rest flows laterally via the RESURF region 4 and the p region 44 and the n region 45 to the cathode 43, which in turn is connected to ground. Because of the inductive load 60, the current does not immediately reach its static final value but instead increases from zero, with a steepness that depends on the level of Vbat, on the magnitude of the inductance of the load 60, and on the voltage drop between the external anode terminal 42 and the cathode 43 of the LVIBGT. This current increase causes a voltage drop, proportional to the current, over the resistor 16, and this voltage drop can be ascertained as explained below.

As shown in FIGS. 7 and 8, the voltage applied to the resistor 16 is picked up at the external anode terminal 42 and a point marked 301 and delivered to the signal detection inputs 101 and 102 of the trigger and evaluation circuit 17. The voltage pickup in each case is done by a respective meander 501 and 502 of the polysilicon resistor 5. The trigger and evaluation circuit 17 finds the difference between the signals applied to the signal detection inputs 101 and 102 and thus ascertains a voltage that is proportional to the current. The voltage thus ascertained is compared, in the trigger and evaluation circuit 17, with two reference voltages. If the voltage ascertained, proportional to the current, reaches the value of one reference voltage, then a status signal is generated at the status output 18 of the trigger and evaluation circuit. If the voltage ascertained reaches the value of the other reference voltage, then the trigger and evaluation circuit 17 reduces the amount of the gate control signal at the trigger output 201 enough to prevent a further current rise through the load 60. The power switch shown here thus protects both itself and the load 60 against excessive currents.

In FIG. 7, the two meanders 501 and 502 of the polysilicon resistor 5 are shown, in terms of their electrical wiring, as 501 and 502. In the cross-sectional view of the LVIGBT, they are also indicated in their primary position and are identified as 5. In FIG. 8, a wiring sketch of the LVIGBT just described, with current limitation, is shown. The structures outlined by dashed lines are integrated on a chip.

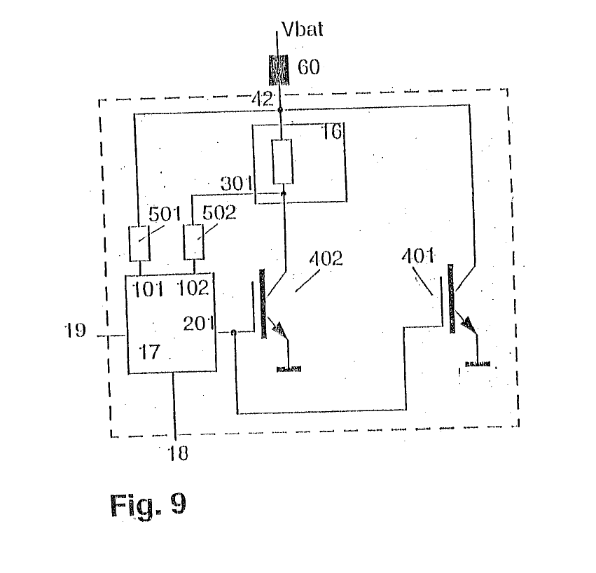

In one advantageous embodiment, shown as a wiring sketch in FIG. 9, only a small part 402 of the LVIGBT is connected via the resistor 16 to the load 60. This small part 402 is then used approximately as a sense cell. The majority 401 of the LVIGBT is connected directly to the load 60. The advantage of this arrangement, over the variant shown in FIG. 8, is a lesser voltage drop over the power component, since only some of the load current flows through the resistor 16.

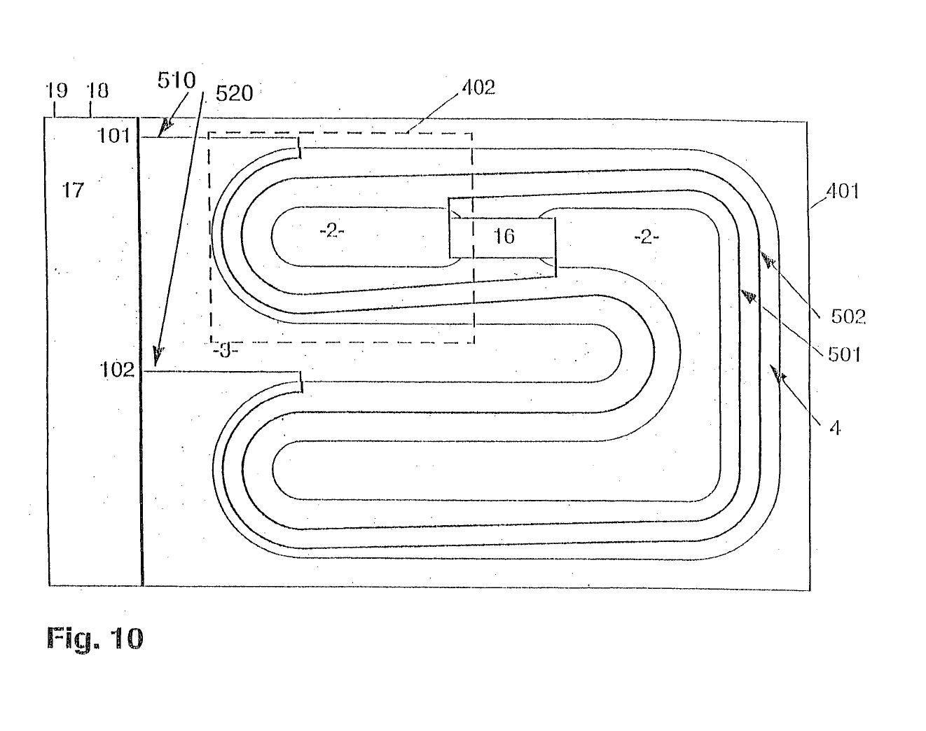

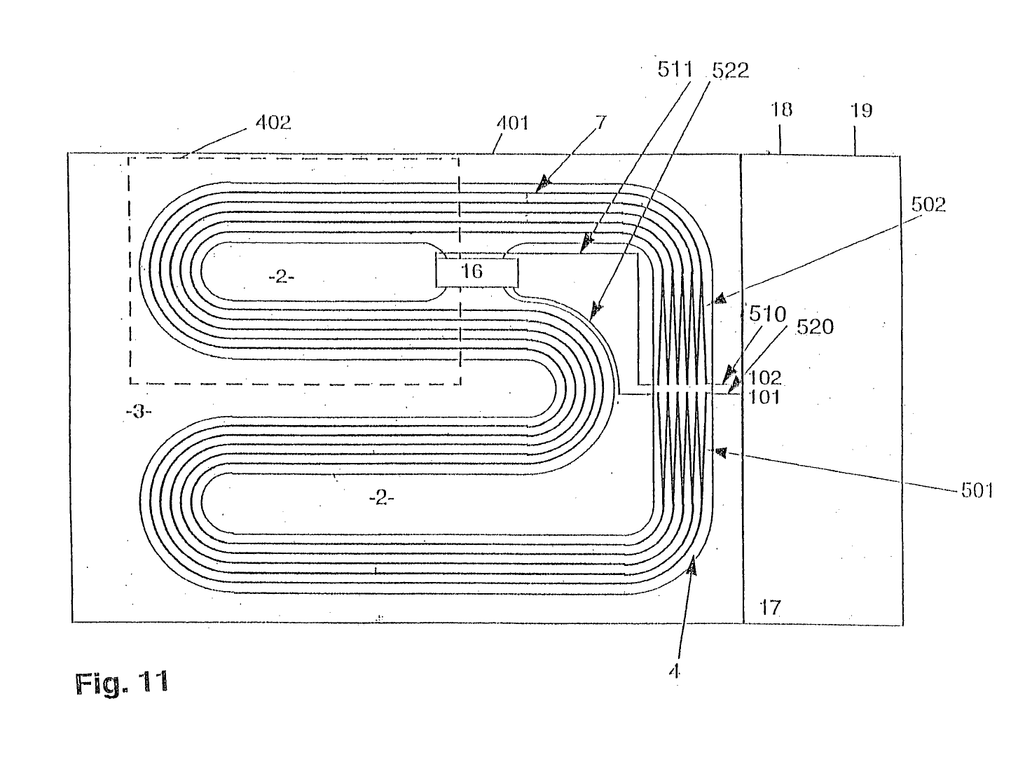

FIGS. 10 and 11 are schematic plan views that show various possible realizations of the voltage pickup via the resistor 16 for the LVIGBT shown in FIG. 9. The variant shown in FIG. 10 includes two polysilicon meanders 501 and 502, which are carried directly to the resistor 16. The resistor 16 here is likewise of polysilicon. The ends, remote from the resistor 16, of the polysilicon meanders 501 and 502 are connected, via metal leads 510 and 520 to the signal detection inputs 101 and 102 of the trigger and evaluation circuit. All the other reference numerals are the same as those in FIG. 9. The variant shown in FIG. 11 includes two polysilicon zigzag meanders 501 and 502, which are carried to the resistor 16 via metal leads 511 and 522. The ends, remote from the resistor 16, of the polysilicon zigzag meanders 501 and 502 are once again connected via the metal leads 510 and 520 to the signal detection inputs 101 and 102 of the trigger and evaluation circuit. All the other reference numerals are the same as those in FIG. 9.

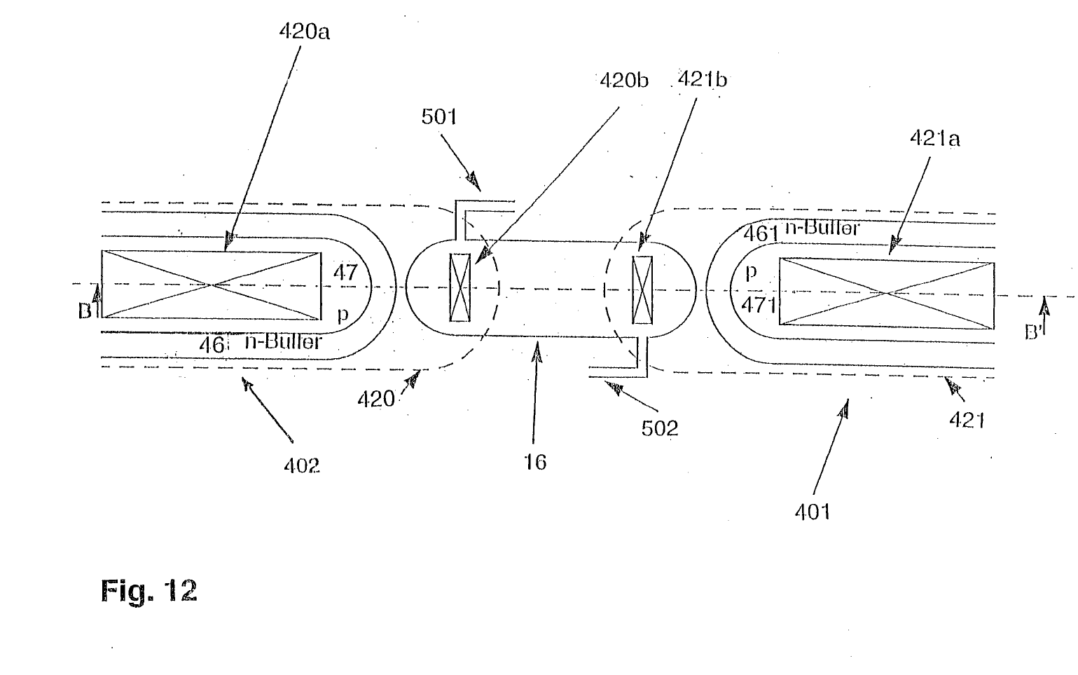

As already noted, FIGS. 10 and 11 show a more-precise view of the course of connection of the polysilicon meanders 501 and 502 to the sense circuit 16 and to the trigger and evaluation circuit 17. The region around the resistor 16 in FIG. 10 that has the connection points of the polysilicon meanders 501 and 502 is shown again in FIG. 12 in plan view, enlarged.

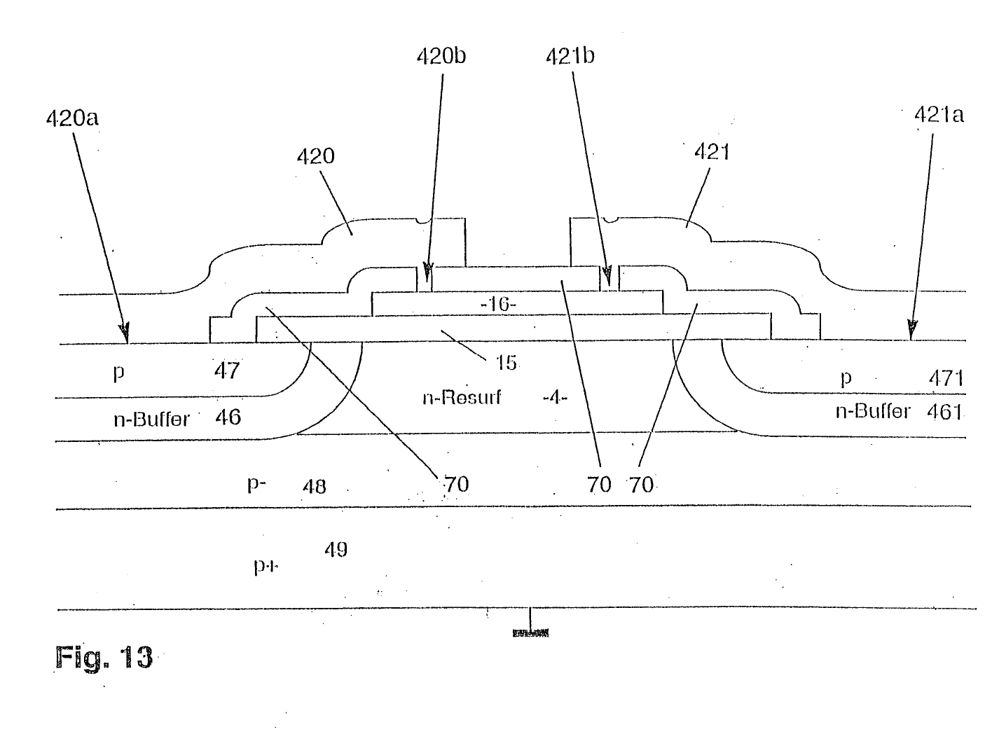

The anode metallizings 420 and 421, which cover the anode diffusions of the two LVIGBT parts 401 and 402 and parts of the resistor 16, are shown in dashed lines. The anode metallizing 420, in region 420a, contacts the p-anode diffusion 47 of the LVGBT part 402 and, in the region 420b, the resistor 16. Correspondingly, the anode metallizing 421, in region 421a, contacts the p-anode diffusion 471 of the LVGBT part 401 and, in region 421b, the resistor 16. The p-anode diffusions 47 and 471 are each embedded in a respective n buffer 46 and 461. A field oxide layer, which electrically insulates the polysilicon meanders 501 and 502 from the RESURF region, and an intermediate oxide film, which insulates the metallizings and the polysilicon from one another, are not shown in FIG. 12 for the sake of simplicity, but they are shown in FIG. 13, which is a cross section taken along the line BB′ of FIG. 12. The passivation layers that are typical in the prior art and are located above the metallizings are shown in neither FIG. 12 nor FIG. 13. FIG. 12 clearly shows that the polysilicon meanders 501 and 502, in the case shown here, are mounted directly on the polysilicon resistor 16.

At the points where a polysilicon meander disposed above the RESURF region 4 ends and the further carrying of signals is performed by means of metal leads, a special construction is required so as not to markedly reduce the blocking-state capability of the component.

Two exemplary embodiments of such constructions will now be explained, taking as an example the cathode side of the LVIGBT shown in FIG. 7.

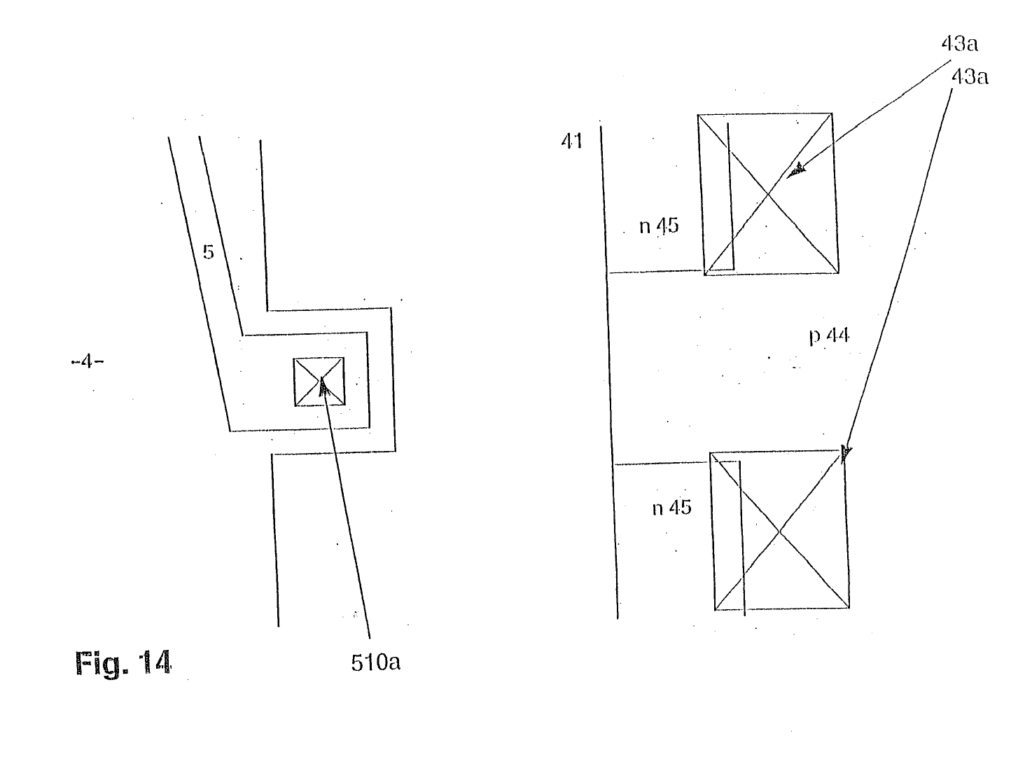

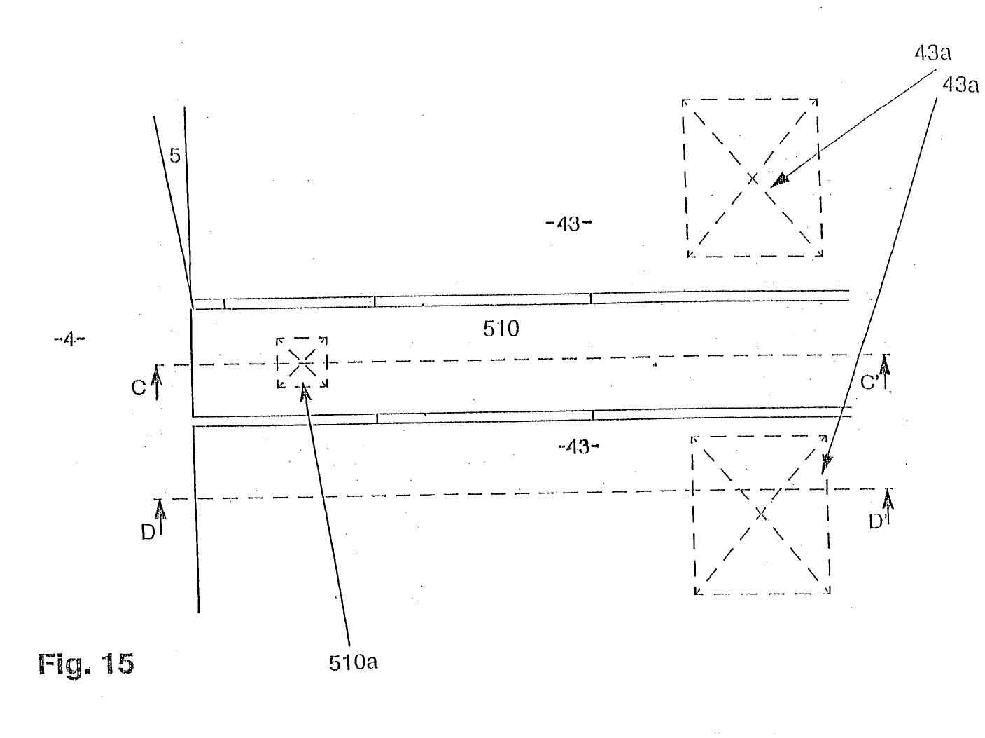

In FIG. 14, in plan view, a first possible realization is shown, without metallizing and without an intermediate dielectric; a plan view with metallizing is shown in FIG. 15. The end of the polysilicon meander 5 is contacted by the metal lead 510 in such a way that this lead, on the side toward the high-voltage region, forms a single flight with the cathode metallizing 43; moreover, all the sharp corners in the polysilicon are covered by the metallizing. Both provisions keep field peaks, which can cause a reduction in the breakdown voltage of the component, slight. Reference numeral 510a indicates the region of the metal lead 510 that contacts the polysilicon meander 5. Reference numeral 43a indicates the regions of the cathode metallizing 43 that contact the silicon surface.

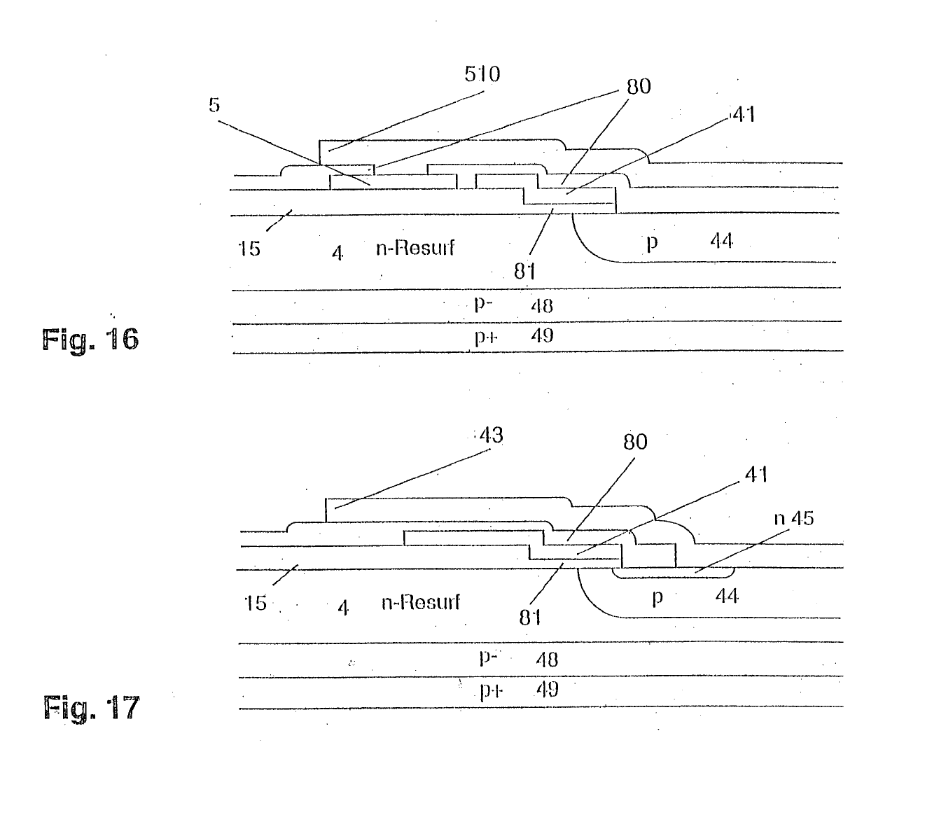

FIGS. 16 and 17 are cross-sectional views taken along the lines CC′ and DD′ of FIG. 15, without the passivation layers, located above the metallizings, that are usual in the prior art. The n region 45 extends no further than the region over which the metal lead 510 extends, which serves to increase the latch-up strength of the component. The intermediate dielectric is marked 60, while the gate oxide is marked 81.

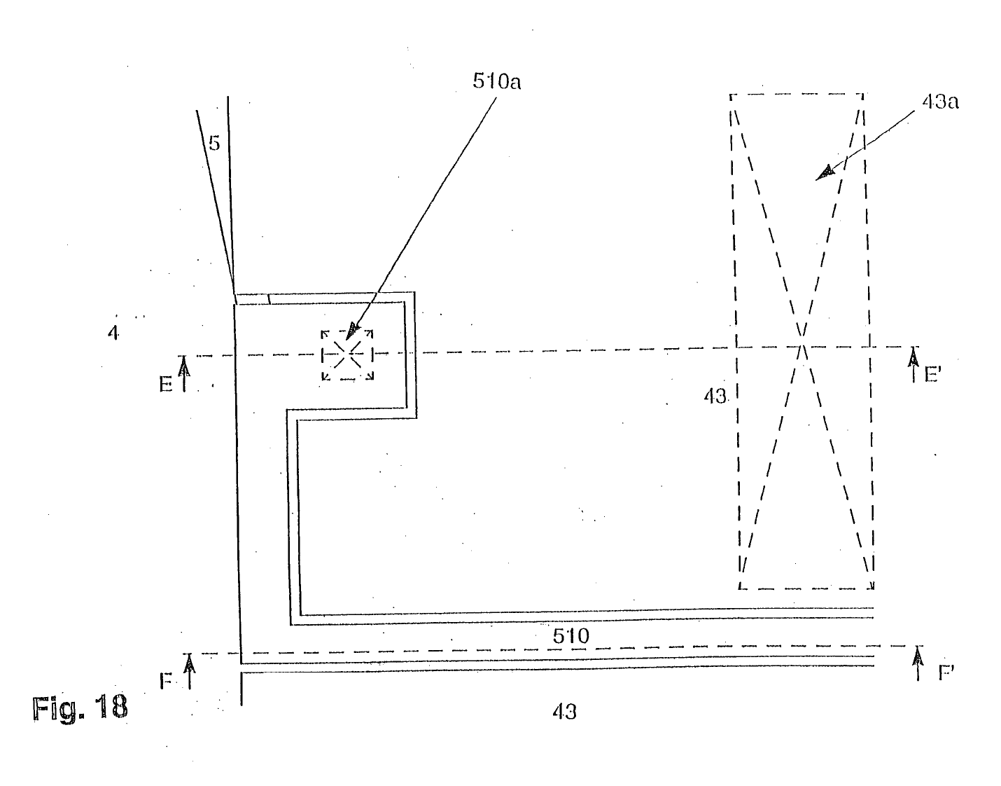

In FIG. 18, a further possible realization, with metallizing and an intermediate dielectric, is shown in plan view. The end of the polysilicon meander 5 is contacted by the metal lead 510 in such a way that this lead, on the side toward the high-voltage region, forms a single flight with the cathode metallizing 43. Moreover, all the sharp corners in the polysilicon are covered by the metallizing. Both provisions keep field peaks, which can cause a reduction in the breakdown voltage of the component, slight.

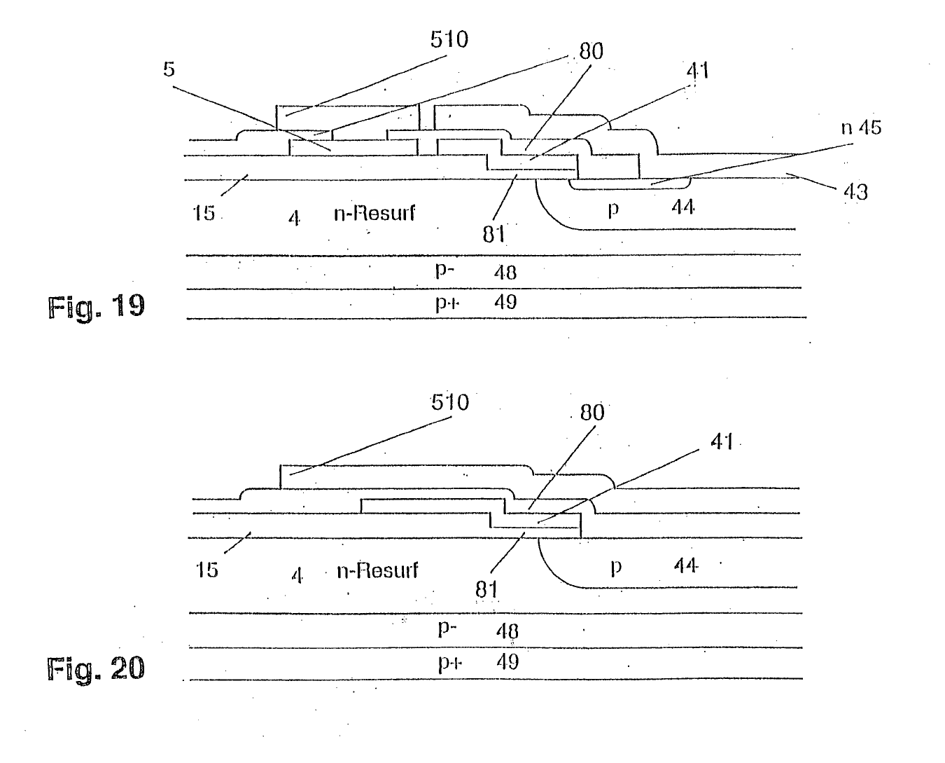

FIGS. 19 and 20 are cross-sectional views taken along the lines EE′ and FF′ of FIG. 18, without the passivation layers, located above the metallizings, that are usual in the prior art. The n region 45 does not extend past the region over which the metal lead 510 extends, which serves to increase the latch-up strength of the component.

The variant shown in FIGS. 18-20 will be selected if the end to be contacted of a polysilicon meander is located in the component that is so unfavorable that the variant described in FIGS. 14-17 cannot be moved around.

The contacting of the high-voltage end of a polysilicon meander can be embodied accordingly.

1. A semiconductor power component (1) having a reduced surface field (RESURF) region (4) disposed between the high-pressure side (2) and the low-pressure side (3),
characterized in that at least one polysilicon resistor (5) for signal transmission is provided between the high-pressure side (2) and the low-pressure side (3); that the polysilicon resistor (5) is disposed above the RESURF region (4); and that the polysilicon resistor (5) is electrically insulated from the RESURF region (4).

2. The semiconductor power component (1) of claim 1, characterized in that the polysilicon resistor (5) is laid in a meandering pattern from the high-pressure side (2) to the low-pressure side (3).

3. The semiconductor power component (1) of one of claims 1 or 2, characterized in that the polysilicon resistor (5) is laid in the form of a spiral meander from the high-pressure side (2) to the low-pressure side (3).

4. The semiconductor power component (1) of one of claims 1 or 2, characterized in that the polysilicon resistor (5) is laid in the form of a zigzag meander from the high-pressure side (2) to the low-pressure side (3).

5. The semiconductor power component (1) of one of claims 1-4, characterized in that the polysilicon resistor (5) is electrically insulated from the RESURF region (4) by at least one field oxide layer (15).

6. The semiconductor power component (1) of one of claims 1-5,
wherein at least one sense circuit (16) and at least one trigger and evaluation circuit (17) are provided for limiting overvoltages or conducting-state currents to allowable maximum values are provided, and
wherein the sense circuit (16) is at the potential of the high-pressure side (2), and the trigger and evaluation circuit (17) is at the potential of the low-pressure side (3),
characterized in that the polysilicon resistor (5) is used for signal transmission between the sense circuit (16) and the trigger and evaluation circuit (17).

7. The semiconductor power component (1) of claim 6, characterized in that the sense circuit (16) and/or the trigger and evaluation circuit (17) is disposed on the same chip as the power component (1).

8. The semiconductor diode (20) of one of claims 1-7, characterized in that the polysilicon resistor (5) is used for signal transmission between the cathode (22) and the anode (21).

9. The semiconductor LIGBT (40) of one of claims 1-7, characterized in that the polysilicon resistor (5) is used for signal transmission between the cathode (43) and the anode (42).

10. The semiconductor LDMOS (30) of one of claims 1-7, characterized in that the polysilicon resistor (5) is used for signal transmission between the drain (33) and the source (32).

11. The semiconductor bipolar transistor (10) of one of claims 1-7, characterized in that the polysilicon resistor (5) is used for signal transmission between the emitter (12) and the collector (13).
